(19) United States
(12) Patent Application Publication
(10) Pub. No.: US 2019/0189396 A1
(43) Pub. Date: Jun. 20, 2019

(54) PLASMA PROCESSING APPARATUS

(71) Applicant: HITACHI HIGH-TECHNOLOGIES CORPORATION, Tokyo (JP)

(72) Inventors: Taku IWASE, Tokyo (JP); Tsutomu TETSUKA, Tokyo (JP); Masakazu ISOZAKI, Tokyo (JP); Kenetsu YOKOGAWA, Tokyo (JP); Masahito MORI, Tokyo (JP)

(21) Appl. No.: 15/906,983

(22) Filed: Feb. 27, 2018

(30) Foreign Application Priority Data
Dec. 15, 2017 (JP) 2017-240725

(51) Int. Cl. H01J 37/32; H01L 21/311; H01L 21/02; C23C 16/507

(52) U.S. Cl. CPC H01J 37/3211; H01J 37/32449; C23C 16/507; H01J 37/32357; H01L 21/02274; H01L 21/311

(57) ABSTRACT

A plasma processing apparatus includes: a processing room disposed inside a vacuum chamber; a sample stage disposed inside the processing room, having an upper surface on which a wafer to be processed is to be mounted; a dielectric discoid member opposed to the upper surface of the sample stage in an upper part of the processing room; a discoid upper electrode disposed having a side covered with the discoid member, the side facing the sample stage, the discoid upper electrode being to be supplied with first radio-frequency power for forming an electric field for forming plasma in the processing room; a coil disposed circumferentially above the processing room outside the vacuum chamber, the coil being configured to generate a magnetic field for forming the plasma; and a lower electrode disposed inside the sample stage, the lower electrode being to be supplied with second radio-frequency power for forming a bias potential on the wafer mounted on the sample stage. A ring-shaped recess and a metal ring-shaped member are provided between the discoid member and the upper electrode, the ring-shaped recess being formed on the discoid member, the metal ring-shaped member being embedded in the ring-shaped recess in contact with the upper electrode.

### CLAIM OF PRIORITY

The present application claims priority from Japanese Patent Application JP 2017-240725 filed on Dec. 15, 2017, the content of which is hereby incorporated by reference into this application.

### BACKGROUND OF THE INVENTION

### 1. Field of the Invention

The present invention relates to a plasma processing apparatus that processes a substrate-shaped sample, such as a semiconductor wafer, mounted on the upper surface of a sample stage disposed in a processing room inside a vacuum chamber, with plasma formed in the processing room. Particularly, the present invention relates to a plasma processing apparatus including: a plate-shaped electrode to be supplied with power for forming plasma, disposed above the upper surface of a sample stage, the electrode being opposed to the upper surface of the sample stage; and a dielectric plate member included in the upper surface of a processing room, below the electrode, the dielectric plate member allowing an electric field for forming the plasma, to pass therethrough.

### 2. Description of the Related Art

Plasma processing is widely used in a manufacturing process of a semiconductor device, the plasma processing including: forming plasma in a processing room inside a decompressed chamber; and etching a film layer to be processed in a film structure including the film layer to be processed and a mask layer previously disposed on the surface of a substrate-shaped sample, such as a semiconductor wafer, disposed in the processing room. In order to form the plasma in the processing room, for example, radio-frequency power having a predetermined frequency is supplied to either of capacitive-coupled parallel plate electrodes including two electrodes of an upper electrode and a lower electrode opposed to each other above and below through a space for plasma formation in the processing room, to form an electric field in the space between the two electrodes, and then gas supplied in the space is excited and dissociated with the electric field, so that the plasma can be formed. The parallel-plate-type plasma processing apparatus attracts charged particles or active particles having high activity (radicals), such as ions, in the plasma formed in the space between the two electrodes, to the film structure on the upper surface of the wafer, to perform the processing.

Recent semiconductor devices have been progressively miniaturized in dimensions, and thus the precision in dimensions after etching processing is continuously in high demand. In order to achieve the demand, a technique of generating and processing high-density plasma with lower pressure, retaining a rate at which the dissociation appropriately occurs lower, has been considered, instead of a conventional technique in which the processing is performed with the dissociation rate of the particles of the gas in the processing room, higher. The power to be supplied in order to generate the plasma, typically has a radio-frequency band of 10 MHz or more in frequency, and a higher frequency has an advantage in high-density plasma generation. However, making the frequency higher reduces the wavelength of an electromagnetic wave, and thus an electric field distribution is ununiform in the plasma processing room. It has been known that the electric field distribution has a distribution having a center portion high that can be expressed with the superposition of Bessel functions.

The increase in the center portion in the electric field increases the electron density of the plasma, and thus uniformity degrades in an etching rate in-plane distribution. The degradation in the etching rate in-plane distribution drops productivity, and thus there is a need to improve the uniformity of the etching rate in the surface of the wafer with an increase in the frequency of the radio-frequency power.

A technique described in JP 2007-250838 A has been known as a conventional technique for resolving the problem. The present conventional technique relates to a plasma processing apparatus including: a discoid first electrode disposed in an upper part of a processing room inside a vacuum chamber, the discoid first electrode being to be supplied with radio-frequency power for plasma formation; and a second electrode disposed inside a sample stage on which a wafer is to be mounted, the second electrode being to be supplied with radio-frequency power, the sample stage being disposed below the processing room. The first electrode has a space at the joint between an electrode support and an electrode plate, the electrode support being disposed above the upper surface of the electrode plate, the electrode support being joined to the electrode plate. The height of the space at a center portion is larger than that of the space at a circumferential portion. This configuration relaxes the ununiformity of the intensity distribution of the electric field between the center portion and circumferential portion of the upper electrode, particularly, a convex distribution high at the center portion, so that the intensity distribution of the electric field in the direction from the center to the circumference, can further approximate uniformity.

Furthermore, according to Ken'etsu Yokogawa et al.; Real time estimation and control oxide-etch rate distribution using plasma emission distribution measurement; Japanese Journal of Applied Physics, Vol. 47, No. 8, 2008, pp. 6854-6857, a technique of increasing power absorption efficiency in a region on the circumferential side of a wafer with an external magnetic field, to cause the distribution of electron density to be formed in a radial direction in a space between electrodes, to further approximate uniformity, has been proposed. According to the conventional technique, increase and decrease in the value of a current to be supplied to a coil, can adjust the intensity of the magnetic field to be formed by the coil, into a value in a desirable range. Thus, even when a condition in which plasma is to be formed varies, the intensity distribution of the plasma or the distribution of charged particles, such as electrons, can be adjusted in response to a variation in an electric field distribution in a processing room. This arrangement has an advantage in that the margin of the condition in which the plasma can be formed further approximating the uniformity, expands.

### SUMMARY OF THE INVENTION

The conventional techniques have not sufficiently considered the following points, resulting in problems.

That is, the configuration in JP 2007-250838 A can make the electric field distribution uniform under a certain condition. However, the distribution of the electric field to be formed and the intensity distribution of the plasma or the distribution of charged particles to be strongly influenced by the electric field, vary in accordance with a condition in the processing room in which plasma is to be formed, including the pressure value in the processing room, the type of gas to be supplied for plasma formation or for wafer processing, the frequency value of the radio-frequency power, and the magnitude of the power. Thus, the conventional technique described in JP 2007-250838 A has, even in a wide-range condition in which plasma is to be formed, a limitation in causing the distribution of the electric field or the intensity distribution of the plasma in the processing room to approximate the uniformity.

The configuration disclosed in Ken'etsu Yokogawa et al.; Real time estimation and control oxide-etch rate distribution using plasma emission distribution measurement; Japanese Journal of Applied Physics, Vol. 47, No. 8, 2008, pp. 6854-6857, has technical difficulty in causing the gradient of the electric field to completely agree with the gradient of the magnetic field in the radial direction of the electrodes disposed through the space in which the plasma is to be formed, and thus a region in which the electron density formed in the space is small is formed at an intermediate location between the center of the electrodes and the circumferential end thereof. Such a “drop” in the electron density causes the intensity of the plasma or the density of charged particles, such as ions, to locally drop in the space below the location of the occurrence of the drop. As a result, a processing characteristic at a location on the upper surface of the wafer disposed below the space, the wafer facing the plasma, the location being positioned below the “drop”, for example, an etching rate also drops in etching processing and ununiformity increases in the deviation of an after-processing processed shape from an expected shape in the in-plane direction of the upper surface of the wafer, and thus there is a risk that processing yield degrades.

The conventional techniques have not considered the problems.

An object of the present invention is to provide a plasma processing apparatus that inhibits ununiformity in the distribution of plasma and further improves processing yield.

The object of the present invention is achieved by a plasma processing apparatus including: a processing room disposed inside a vacuum chamber; a sample stage disposed inside the processing room, the sample stage having an upper surface on which a wafer to be processed is to be mounted; a dielectric discoid member disposed in an upper part of the processing room, the dielectric discoid member being opposed to the upper surface of the sample stage; a discoid upper electrode disposed having a side covered with the dielectric discoid member, the side facing the sample stage, the discoid upper electrode being to be supplied with first radio-frequency power for forming an electric field for forming plasma in the processing room; a coil disposed circumferentially above the processing room outside the vacuum chamber, the coil being configured to generate a magnetic field for forming the plasma; and a lower electrode disposed inside the sample stage, the lower electrode being to be supplied with second radio-frequency power for forming a bias potential on the wafer mounted on the sample stage. A ring-shaped recess and a metal ring-shaped member are provided between the discoid member and the upper electrode, the ring-shaped recess being formed on the discoid member, the metal ring-shaped member being embedded in the ring-shaped recess in contact with the upper electrode.

In addition, the object of the present invention is achieved by a plasma processing apparatus including: a processing room; a lower electrode unit provided to a lower portion of the processing room inside the processing room; an upper electrode unit provided inside the processing room, the upper electrode unit being opposed to the lower electrode unit; a vacuum exhaust unit configured to exhaust for a vacuum inside the processing room; a radio-frequency power applying unit configured to apply radio-frequency power to the upper electrode unit; a magnetic field generating unit provided outside the processing room, the magnetic field generating unit being configured to generate a magnetic field inside the processing room; a radio-frequency bias power applying unit configured to apply radio-frequency bias power to the lower electrode unit; and a gas supplying unit configured to supply processing gas from a side of the upper electrode unit into the processing room. The upper electrode unit includes: an antenna electrode unit configured to receive the radio-frequency power applied from the radio-frequency power applying unit; a gas dispersion plate formed of a conductive material, the gas dispersion plate having a recess formed near a center portion, the gas dispersion plate being in closely contact with the antenna electrode unit near a periphery portion, the gas dispersion plate having a space formed between the gas dispersion plate and the antenna electrode unit, the gas dispersion plate storing the processing gas supplied from the gas supplying unit, into the space; and a shower plate formed of an insulating member, the shower plate covering the gas dispersion plate, the shower plate having a large number of holes formed for supplying the processing gas stored in the space formed between the antenna electrode unit and the gas dispersion plate, into the processing room, the shower plate having an annular groove formed on a side facing the gas dispersion plate, a conductive member being embedded in the annular groove, the conductive member electrically connecting with the gas dispersion plate.

According to the present invention, plasma having excessively high uniformity of electron density from a center portion to a circumferential portion of an electrode, can be generated, so that an etching rate distribution having high uniformity in a surface of a wafer can be achieved.

### BRIEF DESCRIPTION OF THE DRAWINGS

FIG. 1 is a schematic longitudinal sectional view of the schematic configuration of a plasma processing apparatus according to Example of the present invention;

FIGS. 2A and 2B each are an enlarged schematic longitudinal sectional view of the schematic configuration of an antenna unit and the periphery thereof in the plasma processing apparatus according to the present Example illustrated in FIG. 1;

FIGS. 3A to 3D are schematic lower views of modifications of the configuration of the antenna unit according to the present Example illustrated in FIGS. 2A and 2B;

FIG. 4 is a graph exemplifying an etching rate in etching processing to a semiconductor wafer by the plasma processing apparatus according to Example illustrated in FIG. 1;

FIG. 5 is a graph exemplifying the variation in the position of a region in which electron density drops in the radial direction of the wafer, to the variation in the frequency of plasma formation radio-frequency power, in the plasma processing apparatus according to Example illustrated in FIG. 1;

FIG. 6A is a graph exemplifying the distribution of the electron density of plasma in the radial direction of a wafer according to a conventional technique, and FIG. 6B is a graph exemplifying the distributions of the electron density of plasma in the radial direction of a wafer in a plurality of cases where a protrusion is disposed at different positions in the radial direction of the wafer in the plasma processing apparatus according to Example illustrated in FIG. 1;

FIG. 7 is a graph of the relationship between the variation in the ratio between the height of the protrusion and the thickness of a shower plate in the plasma processing apparatus according to Example illustrated in FIG. 1 and the etching rate in the etching processing to the wafer by the plasma processing apparatus; and

FIG. 8 is a graph of the relationship between the ratio between the width of a recess and the diameter of the shower plate in the plasma processing apparatus illustrated in FIG. 1 and the variation in the etching rate in the etching processing of the plasma processing apparatus.

### DESCRIPTION OF THE PREFERRED EMBODIMENTS

An embodiment of the present invention will be described below with reference to the drawings.

### EXAMPLE

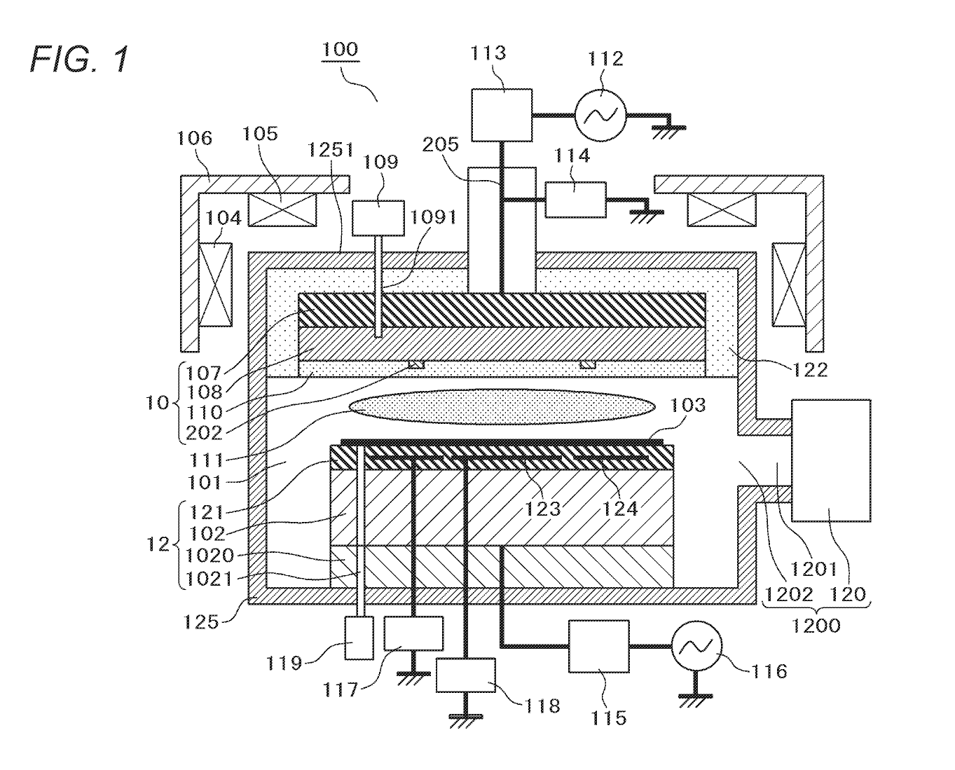

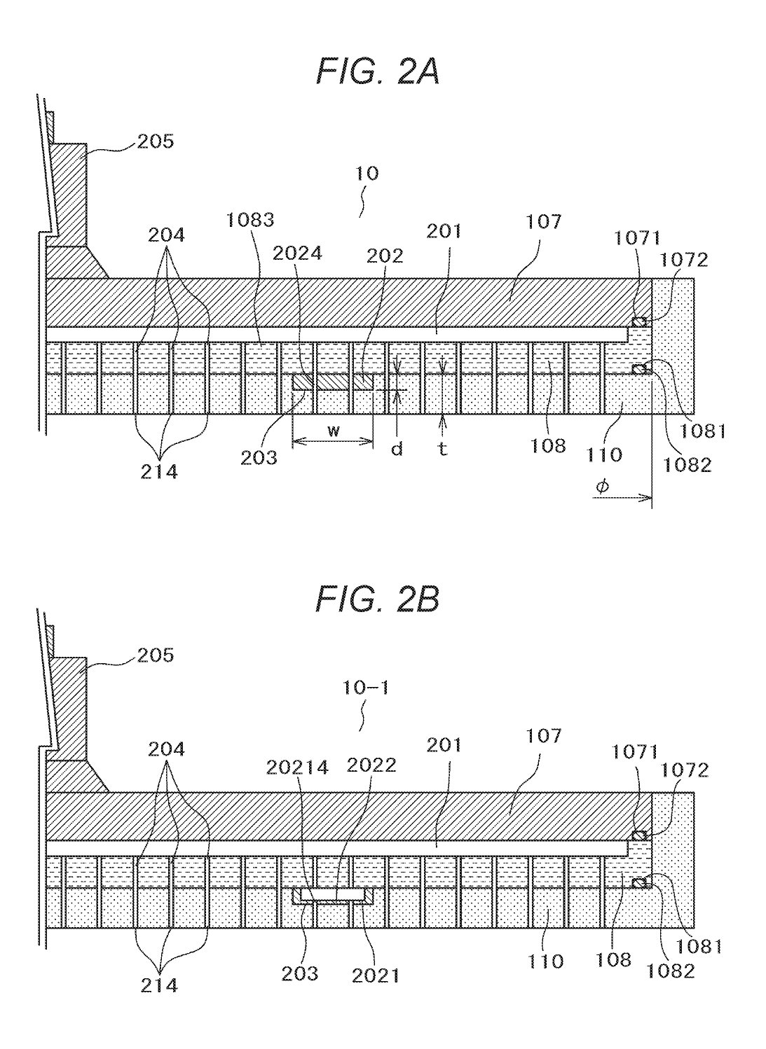

Example 1 according to the present invention will be described with FIG. 1 and FIGS. 2A and 2B. FIG. 1 is a schematic longitudinal sectional view of the schematic configuration of a plasma processing apparatus according to Example of the present invention.

The plasma processing apparatus 100 according to the present Example, is a plasma etching apparatus including: a processing room in which plasma is to be formed with internal decompression; and discoid electrodes to be supplied with radio-frequency power, disposed above and below through a space in which the plasma is to be formed in the processing room. The plasma etching apparatus performs, with the plasma, etching processing to a substrate-shaped sample, such as a semiconductor wafer, disposed on a sample stage disposed inside the processing room, the sample stage including the lower electrode from the upper and lower electrodes, built in. Particularly, the plasma processing apparatus 100 is a parallel-plate-type plasma processing apparatus in which an electric field due to the supplied radio-frequency power is introduced from the surface of the upper electrode into the processing room and additionally a magnetic field formed by coils disposed surrounding the upper and lateral periphery of the processing room outside a vacuum chamber is supplied to the processing room, and then the radio-frequency power and the plasma formed by excitation and dissociation of the atoms or molecules of gas introduced into the processing room are capacitively coupled.

In the configuration illustrated in FIG. 1, the plasma processing apparatus 100 includes a vacuum chamber 125 having a cylindrical shape, the vacuum chamber 125 internally including a processing room 101 having a space having a cylindrical shape. The plasma processing apparatus 100 includes: an upper electrode 10 and a lower electrode 12 disposed above and below inside the vacuum chamber 125 through a space in which plasma 111 is to be formed in the processing room 101; and a radio-frequency power source 112 and a bias formation radio-frequency power source 116 electrically connected to the upper electrode 10 and the lower electrode 12, respectively, the radio-frequency power source 112 and the bias formation radio-frequency power source 116 being configured to supply radio-frequency power having a predetermined frequency to the upper electrode 10 and the lower electrode 12, respectively.

The vacuum chamber 125 includes a vacuum exhaust unit 1200 including an exhaust pump 120, such as a turbo-molecular pump, that exhausts and decompresses the particles of gas and the plasma 111 inside the processing room 101 in communication with the processing room 101. An exhaust opening 1202 facing the processing room 101, of an exhaust duct 1201 forming an exhaust channel disposed between the inlet of the exhaust pump 120 and the processing room 101, is disposed below the upper surface of the lower electrode 12.

The lower electrode 12 includes: a stage (electrode body) 102 formed of a metal member, being a sample stage disposed below the space in which the plasma 111 is to be formed in the processing room 101; an insulating member 1020 electrically insulating the stage 102 from the vacuum chamber 125, provided between the stage 102 and a wall surface of the vacuum chamber 125; and a dielectric film 121 on which a wafer 103 is to be mounted, formed on the stage 102. The lower electrode 12 is disposed, opposed to the upper electrode 10 disposed above.

An antenna unit included in the upper electrode 10, is disposed above the lower electrode 12, opposed to the lower electrode 12. The antenna unit (upper electrode 10) according to the present Example, includes: a conductive antenna body 107 having a discoid shape; a gas dispersion plate 108; and a shower plate 110.

The conductive antenna body 107 having the discoid shape, is electrically connected to the radio-frequency power source 112 that supplies the radio-frequency power in a VHF band, through a waveguide, such as a coaxial cable 205.

The gas dispersion plate 108 is disposed below the antenna body 107, and includes a member having a discoid or cylindrical shape. A gas supply source 109 introduces processing gas into the gas dispersion plate 108, and then the gas dispersion plate 108 internally disperses the processing gas.

The shower plate 110 is disposed below the gas dispersion plate 108, and is included in the ceiling surface of the processing room 101. The shower plate 110 has gas introducing holes being a plurality of through holes through which the processing gas that has been dispersed, passes to be introduced into the processing room 101. A conductive protrusion 202 is embedded, in a ring shape, into a groove formed on the shower plate 110, and the upper surface of the conductive protrusion 202 is in contact with the gas dispersion plate 108.

The antenna unit (upper electrode 10) is disposed inside an upper lid member 1251 of the vacuum chamber 125, through a ring-shaped insulating ring 122 including a dielectric member, such as quartz, for insulation.

The insulating ring 122 on the circumferential side of the antenna unit (upper electrode 10) surrounds, in a ring shape, the periphery of the antenna unit (upper electrode 10) between the antenna unit (upper electrode 10) and the lid member 1251. The lower end surface of the circumferential portion of the insulating ring 122 is disposed at a height position (so-called surface position) the same as or approximate to the height position of the lower surface of the shower plate 110, surrounding the circumference of the shower plate 110, and is included in the ceiling surface of the processing room 101.

According to the present Example, the antenna body 107, the gas dispersion plate 108, and the ring-shaped protrusion 202 included in the upper electrode 10, each are formed of a conductive material, such as aluminum, and the shower plate 110 facing the space in which the plasma 111 is to be formed in the processing room 101, is formed of a dielectric material, such as quartz.

The antenna body 107 is electrically connected to the radio-frequency power source 112 that supplies the radio-frequency power in the VHF band for generating the plasma 111, with the coaxial cable 205 through a first matching device 113. The antenna body 107 is connected to a location at ground potential through a filter 114 such that the antenna body 107 functions as a ground electrode for the radio-frequency power supplied to the lower electrode 12, together with the gas dispersion plate 108.

The filter 114 is designed to block the power for the plasma generation in the VHF band, applied to the antenna body 107 of the antenna unit (upper electrode 10) by the radio-frequency power source 112 and to pass the radio-frequency power for forming a bias potential above the upper surface of the wafer 103, supplied to the stage 102 on which the wafer 103 is mounted, included in the lower electrode 12.

In order to reduce damage to the internal wall of the processing room 101, at the potential of the plasma 111 reduced, with inhibition of the plasma 111 from being excessively dissociated, at the electron density of the plasma 111 set up to approximately 10¹⁰ cm⁻³, the frequency of the radio-frequency power generated by the radio-frequency power source 112 is desirably in a range of 50 to 500 MHz, and thus a frequency of 200 MHz is used according to the present Example. The radio-frequency power having the frequency of 200 MHz, supplied from the radio-frequency power source 112 to the antenna unit (upper electrode 10) through the coaxial cable 205, is supplied to the antenna body 107 and the conductive gas dispersion plate 108 connected to the antenna body 107. Then, the radio-frequency power is emitted from the surface on the side of the shower plate 110 of the gas dispersion plate 108, into the processing room 101 through the shower plate 110.

A first coil 104 and a second coil 105 are disposed surrounding the vacuum chamber 125, the internal antenna unit (upper electrode 10), and the coaxial cable 205, in a ring shape, on the upper and lateral periphery of a cylindrical portion of the processing room 101, outside the vacuum chamber 125.

A direct current supplied from a power source not illustrated, to the first coil 104 and the second coil 105 causes a magnetic field capable of improving the efficiency of heating the plasma 111 occurring inside the processing room 101 due to the radio-frequency power having the frequency of 200 MHz supplied from the radio-frequency power source 112. A conductive yoke 106 disposed covering the circumferential and upper sides of the first coil 104 and the second coil 105, adjusts the magnetic field generated by the first coil 104 and the second coil 105 such that the magnetic field has a distribution in which, when viewed from above the central axis in the upper and lower direction of the antenna unit (upper electrode 10) and the processing room 101, the lines of magnetic force head radially around the central axis, in FIG. 1, head downward to and outward from the processing room 101 (in the left and right direction in FIG. 1), namely, head downward along the central axis and gradually spread.

By, for example, a thermal spraying method, the dielectric film 121 formed of a dielectric material including ceramics, such as alumina or yttria, is disposed covering the upper surface of the stage 102 included in the lower electrode 12 disposed below the processing room 101. The dielectric film 121 forms the mount surface of the lower electrode 12 on which the wafer 103 is mounted.

A plurality of electrostatic adsorption electrodes 123 and 124 is disposed inside the dielectric film 121, in order for the wafer 103 to adsorb and remain onto the dielectric film 121 with electrostatic force formed by supply of direct current power with the wafer 103 mounted on the dielectric film 121. The electrostatic adsorption electrode 123 is connected to a first direct current power source 117, and the electrostatic adsorption electrode 124 is connected to a second direct current power source 118.

A refrigerant channel (not illustrated) disposed multiply coaxially or spirally around the center of the stage 102 having a cylindrical shape, is disposed inside the stage 102 included in the lower electrode 12 through the insulating member 1020, the refrigerant channel being coupled to a temperature controller, such as a chiller unit, not illustrated, through a pipe. A refrigerant, such as a coolant, adjusted at a temperature in a predetermined range by the temperature controller, flows into the refrigerant channel through the pipe not illustrated and passes through and flows out of the refrigerant channel. Then, the refrigerant circularly returns to the temperature controller. This arrangement retains the temperature of the stage 102, furthermore, the temperature of the wafer 103 electrostatically adsorbing on the dielectric film 121 on the upper surface of the stage 102, at a value in a range appropriate to the processing.

Furthermore, the stage 102 and the insulating member 1020 have a path 1021 formed penetrating inside, the path 1021 having an upper end opening disposed at the upper surface of the dielectric film 121, the lower end of the path 1021 being coupled to a heat exchange gas supply source 119.

With the wafer 103 electrostatically adsorbing and remaining on the upper surface of the dielectric film 121 due to the electrostatic adsorption electrode 123 connected to the first direct current power source 117 and the electrostatic adsorption electrode 124 connected to the second direct current power source 118, the heat exchange gas supply source 119 supplies a heat exchange gas, such as He, to the gap between the upper surface of the dielectric film 121 and the back surface of the wafer 103, through the path 1021. Then, heat transfer increases between the two and heat exchange accelerates between the wafer 103 and the stage 102, so that the responsiveness and precision of adjustment of the temperature of the wafer 103 due to the heat exchange with the stage 102, improve.

The exhaust opening 1202 for exhausting the particles of the gas, the plasma, or a reaction product inside the processing room 101, is disposed on the wall surface of the processing room 101 below the upper surface of the stage 102, the exhaust opening 1202 being coupled to the exhaust pump 120 being a vacuum pump included in the vacuum exhaust unit 1200, through the exhaust duct 1201. An exhaust adjustment valve not illustrated that increases or decreases the sectional area of an exhaust path inside the duct to increase or decrease the flow or speed of exhaust, is disposed on the exhaust duct 1201 between the inlet of the exhaust pump 120 and the exhaust opening 1202.

With the configuration described above, first, with the wafer 103 mounted on the upper surface of the dielectric film 121 of the lower electrode 12 by a conveying unit not illustrated, the first direct current power source 117 applies the direct current power to the electrostatic adsorption electrode 123 and the second direct current power source 118 applies the direct current power to the electrostatic adsorption electrode 124, to generate the electrostatic force on the upper surface of the dielectric film 121, so that the wafer 103 electrostatically adsorbs onto the upper surface of the dielectric film 121.

With the wafer 103 adsorbing and remaining on the upper surface of the dielectric film 121 due to the electrostatic force, the processing gas is introduced from the plurality of gas introducing holes 214 (refer to FIGS. 2A and 2B) formed through the shower plate 110 of the antenna unit (upper electrode 10), into the processing room 101, and additionally the exhaust pump 120 of the vacuum exhaust unit 1200 operates to exhaust inside the processing room 101.

At this time, the exhaust adjustment valve not illustrated provided in the vacuum exhaust unit 1200, adjusts the degree of opening to balance the flow or speed of exhaust with the flow or speed of the gas supplied inside the processing room 101 by a gas flow controller (mass flow controller) not illustrated disposed inside the gas supply source 109 or on a gas supply path 1091 between the gas supply source 109 and the gas dispersion plate 108, so that pressure inside the processing room 101 can be adjusted to a value in a range appropriate to the processing of the wafer 103.

In this manner, with the pressure inside the processing room 101 adjusted to the value in the range appropriate to the processing of the wafer 103, the radio-frequency power source 112 applies the radio-frequency power in the VHF band, to the antenna body 107 of the upper electrode 10 through the first matching device 113, and the direct current power source not illustrated applies the direct current to the first coil 104 and the second coil 105. As a result, an electric field is formed from the lower surface (side of the shower plate 110) of the gas dispersion plate 108 of the antenna unit (upper electrode 10) to the shower plate 110, and the magnetic field generated by the first coil 104, the second coil 105, and the yoke 106 is formed inside the processing room 101.

This arrangement excites and dissociates the gas introduced from the plurality of gas introducing holes 214 of the shower plate 110 into the processing room 101, so that the plasma 111 occurs in the space of the processing room 101 between the upper electrode 10 and the lower electrode 12.

The stage 102 formed of the metal member, in the lower electrode 12 is electrically connected to the bias formation radio-frequency power source 116 through a second matching device 115. With the plasma 111 formed, the bias formation radio-frequency power source 116 applies the bias formation radio-frequency power having the predetermined frequency, to the stage 102, so that the bias potential is formed above the wafer 103 electrostatically adsorbing on the dielectric film 121 formed on the upper surface of the stage 102. With this condition retained, energy corresponding to the potential difference between the potential of the plasma 111 and the bias potential, accelerates the charged particles, such as ions, in the plasma 111, so that the charged particles are attracted to the wafer 103 to collide with the wafer 103. This arrangement performs etching processing to the surface of a film layer to be processed included in a film structure previously formed on the upper surface of the wafer 103.

The frequency of the bias formation radio-frequency power applied to the stage 102 by the bias formation radio-frequency power source 116 according to the present Example, is desirably in a range of 400 kHz to 4 MHz sufficiently lower than the frequency of 200 MHz of the radio-frequency power applied to the antenna body 107 by the radio-frequency power source 112, in order not to exert influence on the density distribution of the charged particles or the intensity distribution in the plasma 111. The generation of the plasma 111 due to the bias formation radio-frequency power supplied by the bias formation radio-frequency power source 116, can be negligibly reduced as long as in the frequency range of 400 kHz to 4 MHz.

Meanwhile, the variation width of the energy of the charged particles, such as ions, attracted to the wafer 103, narrows as the frequency of the bias formation radio-frequency power supplied by the bias formation radio-frequency power source 116 rises. Thus, control of the collision energy of the ions, can improve controllability such as adjustment of a processing characteristic, for example, the speed of the etching processing. According to the present Example, the frequency of the bias formation radio-frequency power applied to the stage 102 by the bias formation radio-frequency power source 116, was set to 4 MHz.

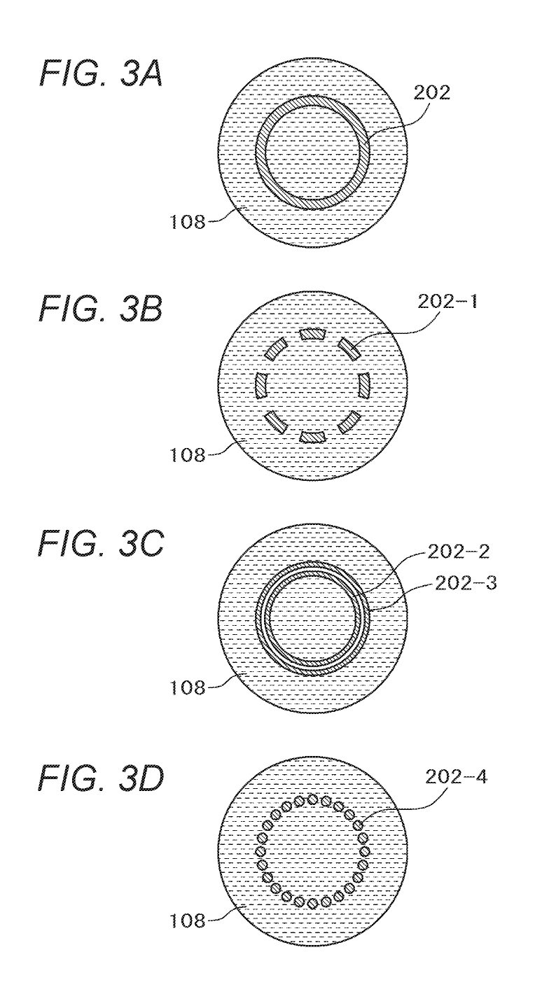

The detailed configuration of the antenna unit (upper electrode 10) according to the present Example, will be described with FIGS. 2A and 2B and FIGS. 3A to 3D. FIGS. 2A and 2B each are an enlarged schematic longitudinal sectional view of the schematic configuration of the antenna (upper electrode 10) and the periphery thereof in the plasma processing apparatus 100 according to the present Example illustrated in FIG. 1. FIGS. 3A to 3D are schematic plan views of modifications of the configuration of the antenna unit (upper electrode 10) illustrated in FIGS. 2A and 2B when viewed from the side of the lower electrode 12.

In the example illustrated in FIG. 2A, the antenna unit (upper electrode 10) has a center portion on the upper surface of the conductive antenna body 107 having the discoid shape, connected with the coaxial cable 205, and the radio-frequency power source 112 supplies the radio-frequency power to the antenna body 107 through the coaxial cable 205. The conductive gas dispersion plate 108 having the discoid shape having a diameter the same as that of the antenna body 107, below the antenna body 107 (side of the lower electrode 12), is connected to the antenna body 107 such that the vicinity of the circumferential portion of the gas dispersion plate 108 is in contact with the antenna body 107.

Furthermore, the dielectric shower plate 110 having a discoid or cylindrical shape, below the gas dispersion plate 108 (side of the lower electrode 12), is coupled to the gas dispersion plate 108, the upper surface of the shower plate 110 covering the lower surface of the gas dispersion plate 108, the upper surface being opposed to the lower surface.

A sealing groove 1081 is formed on the lower surface of the gas dispersion plate 108, namely, on the side facing the shower plate 110, along the circumference. The gas dispersion plate 108 and the shower plate 110 come in contact with each other with a sealing member 1082, such as an O ring, attached to the sealing groove 1081, the sealing member 1082 being sandwiched between the shower plate 110 and the sealing groove 1081. As a result, the inside and outside of the sealing member 1082 are hermetically sealed.

A sealing groove 1071 having a predetermined sectional shape, is formed in the vicinity of the circumferential portion of the lower surface of the antenna body 107, namely, on a portion in contact with the upper surface of the gas dispersion plate 108, along the circumferential portion of the lower surface of the antenna body 107. The antenna body 107 and the gas dispersion plate 108 come in contact with each other with a sealing member 1072, such as an O ring, attached to the sealing groove 1071, the sealing member 1072 being sandwiched between the sealing groove 1071 and the gas dispersion plate 108. As a result, the inside and outside of the sealing member 1072 are hermetically sealed.

Here, the gas dispersion plate 108 has a recess 1083 formed in an internal portion a width away from the cylindrical circumferential surface thereof, along the circumferential surface. The contact between the antenna body 107 and the gas dispersion plate 108 with the sealing member 1072, such as the O ring, attached to the sealing groove 1071, allows the recess 1083 to form a buffer room 201 between the gas dispersion plate 108 and the antenna body 107.

The buffer room 201 is coupled to the gas supply source 109 through the gas supply path 1091, communicating with the gas supply source 109. The gas supply source 109 introduces the gas into the buffer room 201, so that the gas diffuses inside. The gas dispersion plate 108 forming the lower surface of the buffer room 201 and the shower plate 110 disposed below the gas dispersion plate 108, have a plurality of gas introducing holes 204 and the plurality of gas introducing holes 214 penetrating therethrough, respectively, each having a diameter of approximately 0.3 to 1.5 mm, each being fine. The gas supplied from the gas supply source 109, diffusing in the buffer room 201, is introduced into the processing room 101 below through the gas introducing holes 204 formed through the gas dispersion plate 108 and the gas introducing holes 214 formed through the shower plate 110.

According to the present Example, furthermore, the recess 203 is formed in a ring shape around the central axis of the shower plate 110, on the surface in contact with the gas dispersion plate 108, of the shower plate 110. The conductive protrusion 202 formed in the ring shape is embedded into the recess 203. The conductive protrusion 202 has a thickness set in consideration of the depth of the recess 203 such that the upper surface of the conductive protrusion 202 is in contact with the gas dispersion plate 108 with the conductive protrusion 202 embedded in the recess 203. That is, the thickness of the plate-like shower plate 110 is reduced by the depth of the recess 203, at the portion having the recess 203 formed, of the shower plate 110.

With the upper surface of the shower plate 110 and the lower surface of the gas dispersion plate 108 coupled opposed to each other, the conductive protrusion 202 is embedded inside the recess 203 and thus the recess 203 is internally filled with the conductive material of the protrusion 202. The distance from the bottom surface (side of the lower electrode 12) of the protrusion 202 in contact with the gas dispersion plate 108, to the bottom surface (side of the lower electrode 12) of the shower plate 110, is smaller than the distance between the bottom surface (side of the lower electrode 12) of the shower plate 110 at a location different from the recess 203 and the bottom surface (side of the lower electrode 12) of the gas dispersion plate 108.

According to the present Example, the position of the ring-shaped protrusion 202 embedded in the recess 203 formed on the shower plate 110, is arranged such that the circumferential portion of the ring-shaped protrusion 202 is in a region inside the circumferential edge of the wafer 103 when the wafer 103 mounted on the lower electrode 12 is viewed from the side of the upper electrode 10. That is, the circumferential edge of the ring-shaped protrusion 202 coaxially disposed around the axis passing through the center of the wafer 103 in the upper and lower direction, is disposed at a position smaller than the diameter of the wafer 103.

Particularly according to the present Example, the wafer 103 is approximately 300 mm in diameter, and the circumferential edge of the ring-shaped protrusion 202 is disposed at a position in a range of 50 to 100 mm in the radial direction from the center of the gas dispersion plate 108 coaxially disposed. Furthermore, the thickness of the protrusion 202 (height of the protrusion 202) is set to a value of 1 to 5 mm and the size in the radial direction (width of the ring of the protrusion 202 formed in the ring shape) is set to a value of 5 to 30 mm. Particularly, according to the present Example, the position of the central point (an intermediate location between the inner radius and outer radius of the protrusion 202) in the width in the radial direction of the protrusion 202 from the center of the gas dispersion plate 108, was 80 mm and the height and width of the protrusion 202 were 4 and 20 mm, respectively.

With the protrusion 202 inserted into the recess 203 formed on the shower plate 110 and the gas dispersion plate 108 attached to the shower plate 110, the protrusion 202 formed of a conductor, such as metal, is electrically connected to the gas dispersion plate 108 in contact with the gas dispersion plate 108. With this condition retained, when the radio-frequency power source 112 applies the radio-frequency power to the antenna body 107, the radio-frequency power is also supplied to the protrusion 202 through the gas dispersion plate 108. Note that, a gas introducing hole 2024 is formed inside the protrusion 202, penetrating through the protrusion 202, the gas introducing hole 2024 being connected to a gas introducing hole 204 formed through the gas dispersion plate 108 and a gas introducing hole 214 formed through the shower plate 110.

FIG. 2B illustrates a modification of the protrusion 202 formed of the conductor, such as metal, in the antenna unit (upper electrode 10) illustrated in FIG. 2A. A protrusion 2021 formed of a conductor, such as metal, in an antenna unit (upper electrode 10-1) illustrated in FIG. 2B, has a recess 2022 formed on the side facing the gas dispersion plate 108. With the protrusion 2021 connected to the lower surface of the gas dispersion plate 108, abutting on the lower surface of the gas dispersion plate 108, a gap is formed due to the recess 2022 between the protrusion 2021 and the gas dispersion plate 108.

This configuration allows a gas introducing hole 204 formed through the gas dispersion plate 108 to directly communicate with the gap due to the recess 2022 and a gas introducing hole 214 formed through the shower plate 110 to communicate with the gap due to the recess 2022 through a gas introducing hole 20214 formed through the protrusion 2021. This configuration introduces the gas supplied to the buffer room 201, into the processing room 101 at a portion of the protrusion 2021 through the gas introducing hole 204 and the gap due to the recess 2022. Note that, the lower surface (side in contact with the shower plate 110) and side wall surface of the protrusion 2021 in the figure, abut on the inner wall surface and bottom of the recess 203 in which the protrusion 2021 is to be embedded, disposed at a corresponding position on the back surface of the shower plate 110, such that a gap between the protrusion 2021 and the recess 203 is as small as possible.

FIG. 3A is a plan view of the schematic configuration of the gas dispersion plate 108 and the protrusion 202 formed of the conductor, such as metal, disposed below the gas dispersion plate 108, in the antenna unit (upper electrode 10) illustrated in FIG. 2A when viewed from below (side of the lower electrode 12). As illustrated in the present figure, the protrusion 202 is a ring-shaped member coaxially disposed around the center of the gas dispersion plate 108. Note that, the protrusion 202 may include a plurality of members instead of a solid member as illustrated in FIG. 3A. In addition, the protrusion 202 may be radially disposed at a plurality of positions, namely, multiply disposed, instead of at a single radial position.

FIG. 3B exemplifies a protrusion 202-1 including a plurality of arc conductive members circumferentially disposed in a ring shape at radially the same positions from the center when viewed from below, according to a modification of Example illustrated in FIG. 3A. FIG. 3C exemplifies protrusions 202-2 and 202-3 including two conductive ring-shaped members at radially a plurality of positions, namely, at different radial positions, circumferentially integrally formed, when viewed from below. FIG. 3D exemplifies a plurality of conductive members 202-4 each having a cylindrical shape, disposed in a ring shape at radially the same positions around the center.

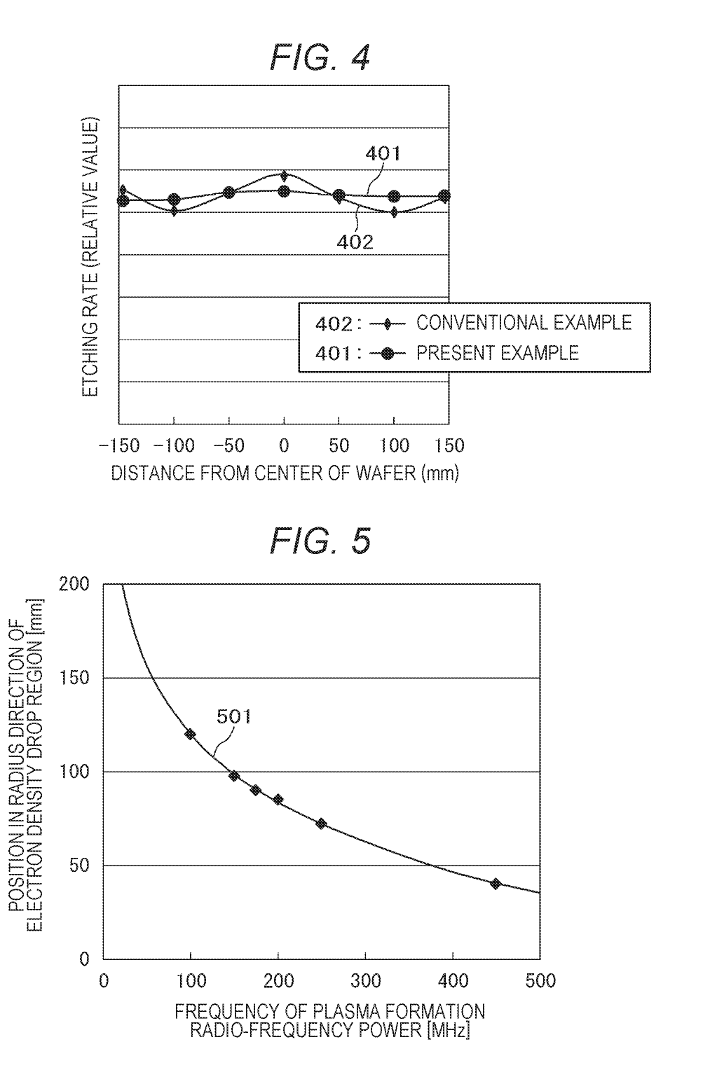

FIG. 4 illustrates the comparison between the distribution of etching speed (etching rate) 401 in the semiconductor wafer 103 subjected to the etching processing by the plasma processing apparatus 100 according to the present Example and the distribution of etching speed (etching rate) 402 in the etching processing performed by a conventional technique in which the antenna unit (upper electrode 10) includes no conductive protrusion 202 (conventional example).

The distribution of the etching rate 401 in the graph illustrated in FIG. 4, exemplifies the in-wafer-plain distribution of the etching rate in the semiconductor wafer 103 subjected to the etching processing by the plasma processing apparatus 100 according to the present Example illustrated in FIG. 1. The horizontal axis represents the distance from the wafer center, and the vertical axis represents the relative value of the etching rate.

The distribution from the wafer center in the distribution of the etching rate 402 illustrated as the conventional example in the graph of FIG. 4, is a result of the etching processing with an etching apparatus including the antenna unit having a configuration different from the configuration of the antenna unit (upper electrode 10) illustrated in FIG. 2A according to the present Example. That is, the etching apparatus performing the etching processing for the distribution of the etching rate 402 illustrated as the conventional example in the graph of FIG. 4, includes no protrusion 202 and no recess 203 in which the protrusion 202 is to be embedded, disposed between the gas dispersion plate 108 and the shower plate 110 described in the present Example. The gas dispersion plate 108 and the shower plate 110 are coupled to each other, the flat lower surface of the gas dispersion plate 108 and the flat upper surface of the shower plate 110 being opposed to each other. Particularly, FIG. 4 exemplifies the result of the etching processing to a resist for photolithography performed by each of the plasma processing apparatus according to the present Example and the etching apparatus according to the conventional technique (conventional example).

The etching processing was performed to a silicon wafer having a diameter of 300 mm coated with the resist for photolithography, with the plasma formed with mixed gas of SF6 and CHF3 as the processing gas in a condition of a pressure of 4 Pa in the processing room, a plasma formation radio-frequency power of 800 W, a frequency of 200 MHz, and a bias formation radio-frequency power of 50 W above the upper surface of the wafer.

For the etching processing performed by the conventional plasma processing apparatus including no conductive protrusion between the gas dispersion plate and the shower plate (in comparison to the configuration of the plasma processing apparatus 100 according to the present Example illustrated in FIG. 1, no conductive protrusion 202 is present and the shower plate 110 has no groove to which the conductive protrusion 202 is to be embedded. The opposed surfaces of the gas dispersion plate 108 and the shower plate 110, are entirely in contact with each other.), as illustrated in FIG. 4, a drop in the etching rate was observed in a region at a radial position of 50 to 100 mm on the wafer in the distribution of the etching rate 402 illustrated as the conventional example.

In contrast to this, the drop in the etching rate was dramatically improved and the variation in the etching rate was reduced in the in-plane radial direction on the upper surface of the wafer, in the distribution of the etching rate 401 in the processing of the plasma processing apparatus 100 according to the present Example.

The frequency of the plasma formation radio-frequency power of the etching apparatus in the conventional example illustrated in FIG. 4, was set to 200 MHz the same as that according to the present Example.

It can be considered that a reason for the occurrence of the drop in the etching rate in the region at the radial position of 50 to 100 mm from the center of the wafer 103 in the distribution of the etching rate 402 illustrated as the conventional example of FIG. 4, is as follows. That is, the intensity distribution of the electric field formed in the processing room by the power having the frequency supplied to the antenna unit, furthermore, the intensity distribution or density distribution of the plasma formed with the electric field, are expressed with the superposition of Bessel functions. As a result, a distribution having a high value at the center portion of the processing room, is acquired. In accordance with the distribution, the electron density of the plasma formed in the processing room by only the electric field, has also a high value at the center portion.

For the etching apparatus that forms the distribution of the electric field, used as the conventional example, a magnetic field forming unit, such as a coil, is provided outside the processing room, to form a magnetic field inside the processing room. Then, the magnetic field is adjusted to improve power absorption efficiency toward the circumferential side of the wafer, so that the electron density can be uniformed to some extent.

In the etching apparatus used as the conventional example described above, the formation of the downward and outward spread magnetic field in the processing room 101 by the first coil 104, the second coil 105, and the yoke 106 disposed coaxially surrounding the processing room around the central axis thereof on the upper and lateral outside of the processing room 101, causes the distribution of the electron density in the processing room 101, to horizontally improve from the center to the outside, to correct the convex distribution of the electric field, so that the electron density in the plasma 111 can further functionally approximate to uniformity.

However, it is technically difficult to cause the gradient of the electric field to agree with the gradient of the magnetic field in the radial direction of the upper electrode 10 and the lower electrode 12 above the lower electrode 12. Thus, a region in which the electron density locally decreases, is formed between the center and circumferential edge of the discoid members of the antenna unit being the upper electrode 10 supplied with the radio-frequency power. The local drop in the electron density, is a factor in the drop in the etching rate at the position in the radial direction of the wafer 103, corresponding to the location, so that the uniformity of the in-wafer-plane etching rate degrades.

Meanwhile, for the distribution of the etching rate 401 illustrated as the present Example, the recess 203 is formed at a coaxial position to the antenna body, on the shower plate 110 attached to the lower surface of the gas dispersion plate 108 electrically connected to the antenna body 107. The conductive protrusion 202 is embedded in the recess 203. The depth of the recess 203 and the height (thickness) of the protrusion 202 are set such that the conductive protrusion 202 is electrically connected to the gas dispersion plate 108 in contact with the gas dispersion plate 108 when the shower plate 110 is combined with the gas dispersion plate 108 with the conductive protrusion 202 embedded in the recess 203.

In this manner, the contact between the gas dispersion plate 108 and the protrusion 202, causes the dielectric shower plate 110 to locally radially increase or decrease in thickness due to the protrusion 202.

Assuming that the dielectric shower plate 110 is a waveguide for electromagnetic waves, a rapid variation in the height of the shower plate 110 corresponding to the waveguide causes susceptance, so that the intensity of the electric field increases, at the recess 203, vertically to the antenna body 107 or the gas dispersion plate 108. In accordance with a radially and locally ring-shaped increase in the intensity of the electric field, the electron density increases in the plasma 111 at a location directly below the protrusion 202 and a region in proximity to the location, above the lower electrode 12 in the processing room 101. As a result, the variation in the etching rate radially decreases in the surface of the wafer 103, so that the uniformity of the etching rate can improve.

According to the present Example, it is important that the conductive protrusion 202 is disposed at a position corresponding to a region in which a drop easily occurs in the electron density of the plasma 111 above the wafer 103 mounted on the lower electrode 12. Meanwhile, the position of a region in which the electron density easily drops in the radial direction of the wafer 103 mounted on the lower electrode 12, varies depending on the frequency for generating the plasma 111.

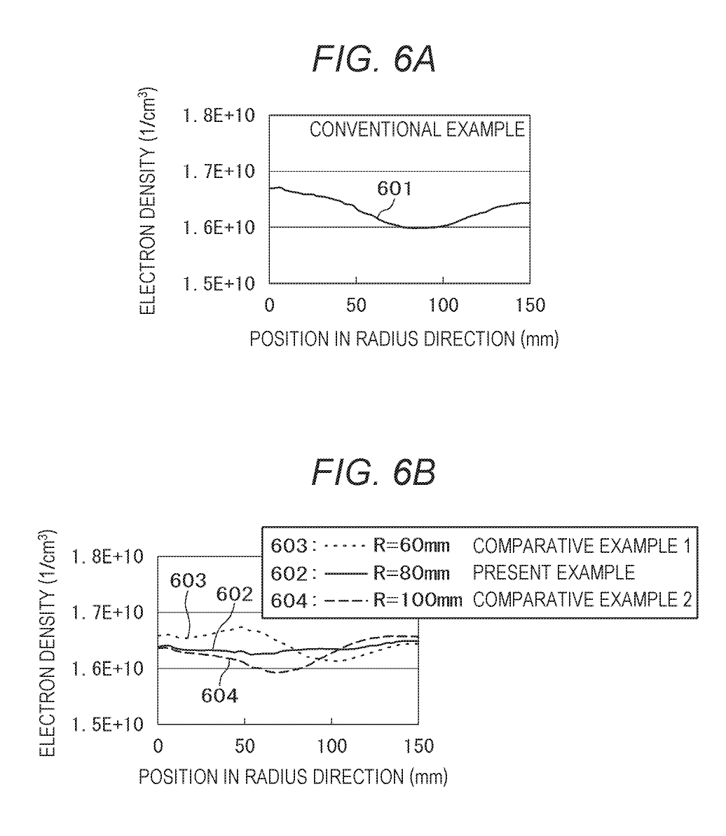

FIG. 5 illustrates an exemplary relationship between the position at which the electron density locally drops on the wafer 103, namely, the position in the radial direction from the center of the wafer 103 mounted on the lower electrode 12 or the center of the upper electrode 10, and the frequency of the radio-frequency power applied from the radio-frequency power source 112 to the upper electrode 10, in the plasma processing apparatus 100 according to the present Example. An exemplary distribution of the electron density when the frequency of the radio-frequency power applied from the radio-frequency power source 112 to the upper electrode 10 in order to generate the plasma 111, varied, will be described with FIGS. 6A and 6B.

FIG. 5 is a graph in which a curve 501 indicates an exemplary variation in the position of the region in which the electron density drops in the radial direction of the wafer 103 mounted on the lower electrode 12, to the variation in the frequency of the plasma formation radio-frequency power supplied from the radio-frequency power source 112 to the upper electrode 10, in the plasma processing apparatus 100 according to the present Example illustrated in FIG. 1.

As indicated with the curve 501 of FIG. 5, the distribution of the electron density (occurrence position of the region in which the electron density drops in the radial direction of the wafer 103) varies in accordance with the frequency of the plasma formation radio-frequency power applied from the radio-frequency power source 112 to the upper electrode 10. That is, it can be seen that the region in which the electron density locally drops, approximates to the circumferential edge of the wafer 103 as the frequency of the plasma formation radio-frequency power decreases.

From FIG. 5, it can be seen that the region in which the electron density locally drops, is formed at a position of approximately 80 mm in the radial direction from the center of the wafer 103 at the frequency of 200 MHz of the plasma formation radio-frequency power used in the present Example. According to the present Example, the protrusion 202 is disposed such that the center of the width of the protrusion 202 is positioned at a position corresponding to this position, specifically, at a position of 80 mm in the radial direction from the center of the gas dispersion plate 108.

FIG. 6A is a graph exemplifying the distribution of the electron density of the plasma 601 in the radial direction of the wafer mounted on the lower electrode 12, in the plasma processing apparatus used as the conventional example including: no conductive protrusion 202; no groove in which the conductive protrusion 202 is to be embedded, formed on the shower plate 110; and the opposed surfaces of the gas dispersion plate 108 and the shower plate 110 entirely being in contact with each other, in comparison to the configuration according to the present Example described in FIG. 1, as described in FIG. 4.

FIG. 6B is a graph exemplifying the distribution of the electron density of the plasma 602 in the radial direction of the wafer in a plurality of cases where the conductive protrusion 202 was disposed at different positions in the radial direction of the wafer in the plasma processing apparatus 100 according to the present Example illustrated in FIG. 1.

FIG. 6B illustrates results of the distribution of the electron density of the plasma 603 for the protrusion 202 disposed having the center in width at a position of 60 mm in the radial direction of the wafer 103 as Comparative Example 1 and the distribution of the electron density of the plasma 604 for the protrusion 202 disposed having the center in width at a position of 100 mm in the radial direction of the wafer 103 as Comparative Example 2, in comparison to the present Example for the protrusion 202 disposed having the center in width at the position of 80 mm in the radial direction.

The variation is reduced in the value of the electron density in the radial direction, in the distribution of the electron density of the plasma 602 according to the present Example in which the protrusion 202 was disposed at the position of 80 mm in the radial direction of the wafer 103, illustrated in FIG. 6B, in comparison to the distribution of the electron density of the plasma 601 according to the conventional example illustrated in FIG. 6A in which the region in which the electron density locally drops in the radial direction of the wafer 103, is present with no countermeasure against the local drop of the electron density in the radial direction of the wafer 103.

Meanwhile, in the distributions of the electron density of the plasma 603 and 604 according to Comparative Examples 1 and 2 in which the protrusion 202 was disposed at 60 and 100 mm in the radial direction illustrated in FIG. 6B, respectively, the region in which the electron density locally drops, moves in the radial direction in comparison to the conventional example. However, since the degree of improvement for the drop of the electron density may be small, the difference between a maximum value and a minimum value formed, is larger than the local drop in the distribution of the electron density of the plasma 601 in the conventional example illustrated in FIG. 6A.

As described above, it can be seen that an appropriate positional range is present for the disposition of the conductive protrusion 202 electrically integrated with the gas dispersion plate 108 in contact with the gas dispersion plate 108, in order to effectively reduce the variation in the electron density in the radial direction of the wafer 103. It can be seen that the disposition of the conductive protrusion 202 in the range is important in order to improve the uniformity of the plasma processing in the surface of the wafer 103 so that the yield of the plasma processing improve.

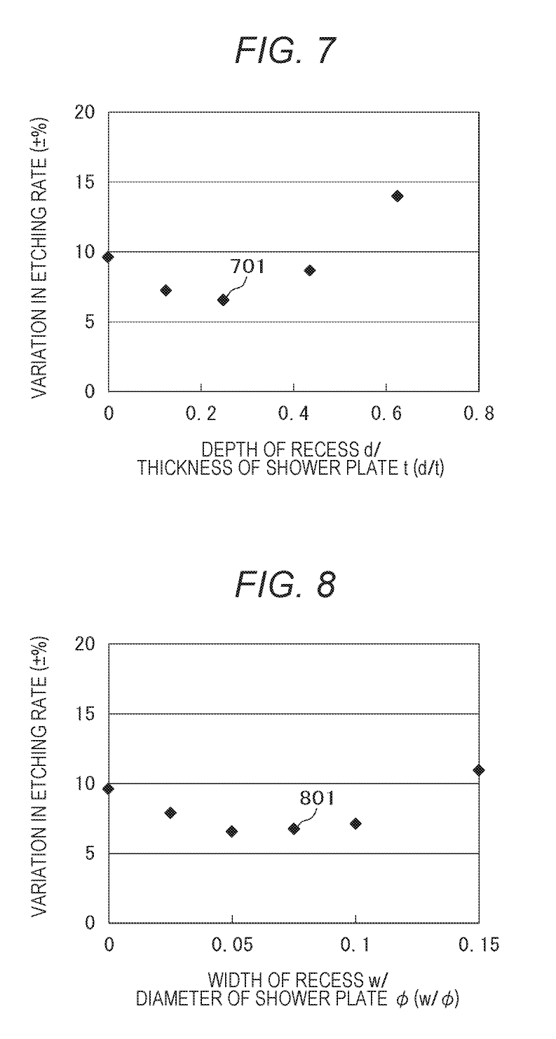

Next, the relationship between the height of the protrusion 202 and the variation in the etching rate, will be described with FIG. 7. FIG. 7 is a graph of the relationship between the variation in the ratio between the height (thickness) of the conductive protrusion 202 and the thickness of the shower plate 110 in the plasma processing apparatus 100 according to the present Example illustrated in FIG. 1 and the variation in the etching rate 701 in the etching processing to the wafer 103 by the plasma processing apparatus 100.

In the present figure, the height (thickness) of the conductive protrusion 202 and the depth of the recess 203 of the shower plate 110 each are defined as d, and the thickness of the shower plate 110 is defined as t. According to the present Example, the thickness t of the shower plate 110 is 16 mm. The relationship between the thickness t of the shower plate 110 and the depth d of the recess 203 is defined as d/t. Illustrated is the root-mean-square value (variation) in deviation between the average value of values in the etching rate at positions in the radial direction from the center to the circumferential edge of the wafer 103 acquired in the etching processing to the wafer 103 with the variation in d/t and the values in the etching rate at the positions.

As illustrated in FIG. 7, the variation in the etching rate 701 decreases and improves as the value of d/t increases from zero, but the variation inversely increases as the value of d/t is 0.5 or more. A reason for this can be considered as follows. With the increase of the value of d/t, the electron density largely increases in amount at a location in the processing room 101 below the protrusion 202 due to the deposition of the protrusion 202. The etching rate locally increases at a portion corresponding to the protrusion 202 for d/t of 0.5 or more, and thus the variation in the etching rate 701 degrades.

Next, the relationship between the width of the protrusion 202 or the width w of the recess 203 and the variation in the etching rate, will be described with FIG. 8. FIG. 8 is a graph of the relationship between the ratio (w/φ) between the width w of the recess 203 and the diameter φ of the shower plate 110 (diameter of a portion into which the antenna body 107 and the gas dispersion plate 108 are inserted in the shower plate 110, in FIG. 2A) in the plasma processing apparatus 100 illustrated in FIG. 1 and the variation in the etching rate 801 in the etching processing performed by the plasma processing apparatus 100.

Here, approximating that the width of the protrusion 202 and the width w of the recess 203 of the shower plate 110 agree with each other or the width w of the recess 203 is slightly larger than the width of the protrusion 202, the relationship between the diameter φ of the shower plate 110 and the width w of the recess 203 is defined as w/φ. According to the present Example, the diameter of the shower plate 110 was 400 mm.

Similarly to FIG. 7, FIG. 8 illustrates the root-mean-square value (variation) in deviation between the average value of values in the etching rate at positions in the radial direction from the center to the circumferential edge of the wafer 103 acquired in the etching processing to the wafer 103 with the variation in w/φ and the values in the etching rate at the positions.

As illustrated in the present figure, it can be seen that as the ratio of the width w of the recess 203 to the diameter φ of the shower plate 110 increases from zero, the variation in the etching rate 801 gradually decreases at up to a value in the ratio, and the variation increases again as the ratio further increases. That is, it can be seen that the variation in the etching rate 801 has a minimum value at a predetermined ratio w/φ.

A reason for the variation in the etching rate in the relationship illustrated in FIG. 8, can be considered as follows. The region in which the electron density of the plasma 111 increases due to the concentration of the electric field, becomes locally small as the width w of the recess 203 (width of the protrusion 202) decreases. The electron density of the plasma 111 increases in a wider region as the width increases.

In that point, it can be seen that the ratio between the width w of the recess 203 and the diameter φ of the shower plate 110 has an appropriate positional range in order to effectively reduce the variation in the etching rate 801 in the radial direction of the electron density. With the configuration having no recess 203 formed and no protrusion 202 provided, increase of the electron density in a range wider than the region in which the etching rate drops, degrades the uniformity of the etching rate in comparison to the case of the optimization of the width w of the recess 203. According to the present Example, as illustrated in FIG. 8, setting the ratio between the width w of the recess 203 and the diameter φ of the shower plate 110, to less than 0.14, decreases the variation in the etching rate 801.

Note that, according to Example described above, the configuration has been described in which the conductive protrusion 202 is electrically connected in contact with the gas dispersion plate 108, with the conductive protrusion 202 embedded in the recess 203 formed on the shower plate 110, the conductive protrusion 202 and the gas dispersion plate 108 being separately formed. However, the conductive protrusion 202 and the gas dispersion plate 108 may be integrally formed.

As described above, according to Example of the present invention, the variation is reduced in the intensity distribution of the electric field formed in the processing room 101, in the radial direction from the center to the circumferential edge of the wafer 103. As a result, the variation is reduced in the electron density in the processing room 101, in the radial direction of the wafer 103. Thus, the distribution in the radial direction of the intensity or density of the plasma 111 formed in the processing room 101, further approximates to uniformity.

Furthermore, in the etching processing to the wafer 103 with the plasma 111, the variation is reduced in a processing characteristic with the plasma, such as the etching rate, between locations on the upper surface of the wafer 103 in the radial direction, so that processing yield improves.

What is claimed is:

1. A plasma processing apparatus comprising:
a processing room disposed inside a vacuum chamber;
a sample stage disposed inside the processing room, the sample stage having an upper surface on which a wafer to be processed is to be mounted;
a dielectric discoid member disposed in an upper part of the processing room, the dielectric discoid member being opposed to the upper surface of the sample stage;
a discoid upper electrode disposed having a side covered with the discoid member, the side facing the sample stage, the discoid upper electrode being to be supplied with first radio-frequency power for forming an electric field for forming plasma in the processing room;
a coil disposed circumferentially above the processing room outside the vacuum chamber, the coil being configured to generate a magnetic field for forming the plasma; and
a lower electrode disposed inside the sample stage, the lower electrode being to be supplied with second radio-frequency power for forming a bias potential on the wafer mounted on the sample stage,
wherein a ring-shaped recess and a metal ring-shaped member are provided between the discoid member and the upper electrode, the ring-shaped recess being formed on a side of the discoid member, the metal ring-shaped member being embedded in the ring-shaped recess in contact with the upper electrode.

2. The plasma processing apparatus according to claim 1, wherein the first radio-frequency power has a range of 50 to 500 MHz in frequency.

3. The plasma processing apparatus according to claim 1, wherein the magnetic field has lines of magnetic force formed downward and gradually spreading around a central axis of the magnetic field, and
the metal ring-shaped member is positioned on a side of the central axis from directly above a circumferential edge of a mount surface of the wafer on the sample stage on which the wafer is to be mounted.

4. The plasma processing apparatus according to claim 1, wherein the metal ring-shaped member is integrally formed with the upper electrode.

5. The plasma processing apparatus according to claim 1, wherein the dielectric discoid member is disposed having an upper surface having a gap to a lower surface of the upper electrode, and has a lower surface having a plurality of introducing holes for processing gas to be supplied into the processing room.

6. A plasma processing apparatus comprising:
a processing room;
a lower electrode unit provided to a lower portion of the processing room inside the processing room;
an upper electrode unit provided inside the processing room, the upper electrode unit being opposed to the lower electrode unit;
a vacuum exhaust unit configured to exhaust for a vacuum inside the processing room;
a radio-frequency power applying unit configured to apply radio-frequency power to the upper electrode unit;
a magnetic field generating unit provided outside the processing room, the magnetic field generating unit being configured to generate a magnetic field inside the processing room;
a radio-frequency bias power applying unit configured to apply radio-frequency bias power to the lower electrode unit; and
a gas supplying unit configured to supply processing gas from a side of the upper electrode unit into the processing room,
wherein the upper electrode unit includes:
an antenna electrode unit configured to receive the radio-frequency power applied from the radio-frequency power applying unit;
a gas dispersion plate formed of a conductive material, the gas dispersion plate having a recess formed near a center portion, the gas dispersion plate being in closely contact with the antenna electrode unit near a periphery portion, the gas dispersion plate having a space formed between the gas dispersion plate and the antenna electrode unit, the gas dispersion plate storing the processing gas supplied from the gas supplying unit, into the space; and
a shower plate formed of an insulating member, the shower plate covering the gas dispersion plate, the shower plate having a large number of holes formed for supplying the processing gas stored in the space formed between the antenna electrode unit and the gas dispersion plate, into the processing room, the shower plate having an annular groove formed on a side facing the gas dispersion plate, a conductive member being embedded in the annular groove, the conductive member electrically connecting with the gas dispersion plate.

7. The plasma processing apparatus according to claim 6, wherein the conductive member embedded in the annular groove of the shower plate, is formed of an annular conductive member, and is electrically connected to the gas dispersion plate in contact with the gas dispersion plate.

8. The plasma processing apparatus according to claim 6, wherein the conductive member embedded in the annular groove of the shower plate, is integrally formed with the gas dispersion plate.
